(19) United States
(12) Patent Application Publication
(10) Pub. No.: US 2026/0033340 A1
(43) Pub. Date: Jan. 29, 2026

(54) SEMICONDUCTOR DEVICE

(71) Applicant: Renesas Electronics Corporation, Tokyo (JP)

(72) Inventors: Hiroaki SEKIKAWA, Tokyo (JP); Yuki YAMAMOTO, Tokyo (JP); Hiroyuki ARIE, Tokyo (JP)

(21) Appl. No.: 19/217,104

(22) Filed: May 23, 2025

(30) Foreign Application Priority Data
Jul. 23, 2024 (JP) 2024-117581

(51) Int. Cl. H01L 23/58; H01L 21/78

(52) U.S. Cl. CPC H01L 23/585; H01L 21/78

(57) ABSTRACT

A semiconductor device includes a semiconductor substrate, a sealing ring, and at least one routing wiring. The semiconductor substrate has a peripheral region in plan view. The sealing ring is formed on the peripheral region. The sealing ring includes a plurality of conductors and a plurality of first plugs. Each of the plurality of conductors is laminated along a thickness direction of the semiconductor substrate and extends along the peripheral region in plan view. Each of the plurality of conductors has an outer edge and an inner edge in plan view. The plurality of conductors includes a first conductor located at the uppermost layer and a plurality of second conductors located below the first conductor. The outer edge of the first conductor is positioned outside any of outer edges of each of the plurality of second conductors.

### CROSS-REFERENCE TO RELATED APPLICATIONS

The disclosure of Japanese Patent Application No. 2024-117581 filed on Jul. 23, 2024, including the specification, drawings and abstract is incorporated herein by reference in its entirety.

### BACKGROUND

The present disclosure relates to a semiconductor device.

A semiconductor device described in Japanese Unexamined Patent Application Publication No. 2019-114673 (Patent Document 1) includes a semiconductor substrate and a sealing ring formed on the peripheral region of the semiconductor substrate. The sealing ring comprises a plurality of conductors and a plurality of plugs. The conductors are laminated. Each of the plugs connects two adjacent conductors. However, one of the plugs connects the conductor located at the lowest layer to the semiconductor substrate. A passivation film covers the conductor located at the uppermost layer.

### SUMMARY

In plan view, a pad for inspection may be formed at a position overlapping with a scribe line. If a routing wiring connected to this pad is formed at a position overlapping with the scribe line in plan view, a width of the scribe line increases, reducing a number of semiconductor devices that can be obtained from a single wafer. Other problems and novel features will become apparent from the description of this specification and the accompanying drawings.

A semiconductor device of the present disclosure includes a semiconductor substrate, a sealing ring, and at least one routing wiring. The semiconductor substrate has a peripheral region in plan view. The sealing ring is formed on the peripheral region. The sealing ring comprises a plurality of conductors and a plurality of first plugs. Each of the conductors is laminated along a thickness direction of the semiconductor substrate and extends along the peripheral region in plan view. Each conductor has an outer edge and an inner edge in plan view. The conductors include a first conductor located at the uppermost layer and a plurality of second conductors located below the first conductor. The outer edge of the first conductor is positioned outside any of the outer edges of the plurality of second conductors. Each of the plurality of first plugs connects between the first conductor and one of the plurality of second conductors adjacent to the first conductor, between two adjacent second conductors, or between the peripheral region and one of the second conductors adjacent to the peripheral region, and extends along the peripheral region in plan view. Each of the at least one routing wiring is positioned between the outer edge of the first conductor and the outer edges of the plurality of second conductors in plan view. Each routing wiring is formed on or within the peripheral region so as to be positioned below the first conductor.

According to the semiconductor device of the present disclosure, it is possible to form the routing wiring while suppressing the reduction in the number of semiconductor devices that can be obtained from the single wafer.

### BRIEF DESCRIPTION OF THE DRAWINGS

FIG. 1 is a plan view of a semiconductor device DEV1.

FIG. 2 is a partial enlarged view of FIG. 1.

FIG. 3 is a cross-sectional view of the semiconductor device DEV1 at III-III in FIG. 2.

FIG. 4 is a cross-sectional view of the semiconductor device DEV1 at IV-IV in FIG. 2.

FIG. 5A is a cross-sectional view of the semiconductor device DEV1 according to a first modified example.

FIG. 5B is a plan view of the semiconductor device DEV1 according to a second modified example.

FIG. 6 is a manufacturing process diagram of the semiconductor device DEV1.

FIG. 7 is a cross-sectional view for explaining an interlayer insulating film forming step S3.

FIG. 8 is a cross-sectional view for explaining a plug forming step S4.

FIG. 9 is a cross-sectional view for explaining a wiring forming step S5.

FIG. 10 is a cross-sectional view for explaining a passivation film forming step S6.

FIG. 11 is an enlarged plan view of the semiconductor device DEV1 at a scribe line SCL before a dicing step S7 is performed.

FIG. 12 is an enlarged plan view of a semiconductor device DEV2.

FIG. 13 is a cross-sectional view of the semiconductor device DEV2 at XIII-XIII in FIG. 12.

FIG. 14 is an enlarged plan view of the semiconductor device DEV2 at the scribe line SCL before the dicing step S7 is performed.

FIG. 15 is an enlarged plan view of the semiconductor device DEV2 according to a modified example.

FIG. 16 is an enlarged plan view of a semiconductor device DEV3.

FIG. 17 is a cross-sectional view of the semiconductor device DEV3 at XVII-XVII in FIG. 16.

FIG. 18 is an enlarged plan view of the semiconductor device DEV3 at the scribe line SCL before the dicing step S7 is performed.

FIG. 19 is an enlarged plan view of the semiconductor device DEV3 according to the first modified example.

FIG. 20 is a cross-sectional view of the semiconductor device DEV3 according to the second modified example.

FIG. 21 is a cross-sectional view of the semiconductor device DEV3 according to a third modified example.

FIG. 22 is a cross-sectional view of the semiconductor device DEV3 according to a fourth modified example.

FIG. 23 is a cross-sectional view of the semiconductor device DEV3 according to a fifth modified example.

FIG. 24 is an enlarged plan view of the semiconductor device DEV3 according to the fifth modified example at the scribe line SCL before the dicing step S7 is performed.

FIG. 25 is a cross-sectional view of the semiconductor device DEV3 according to a sixth modified example.

FIG. 26 is a cross-sectional view of the semiconductor device DEV3 according to a seventh modified example.

FIG. 27 is a cross-sectional view of the semiconductor device DEV3 according to an eighth modified example.

FIG. 28 is a cross-sectional view of the semiconductor device DEV3 according to a ninth modified example.

### DETAILED DESCRIPTION

Details of embodiments of the present disclosure will be described with reference to the drawings. In the following drawings, the same or corresponding parts are denoted by the same reference numerals, and redundant description will not be repeated.

### First Embodiment

A semiconductor device DEV1 related to the first embodiment will be described.

### (Configuration of Semiconductor Device DEV1)

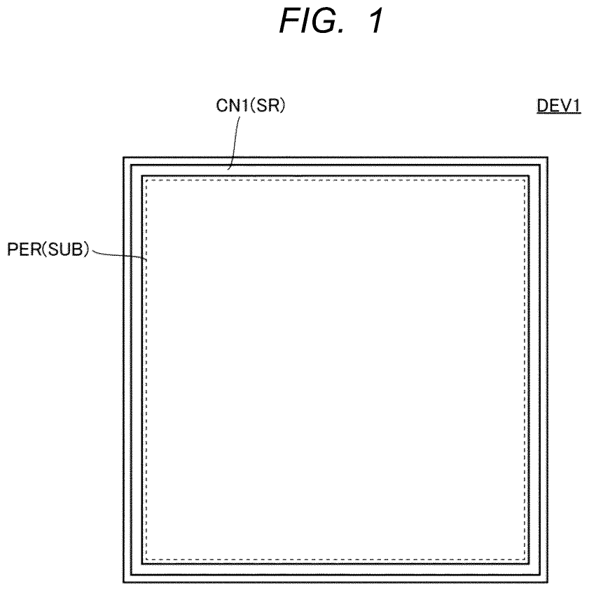

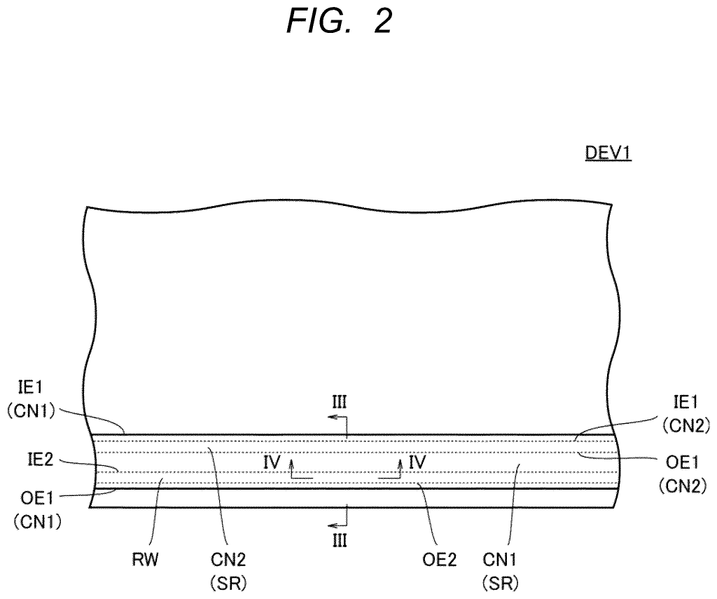

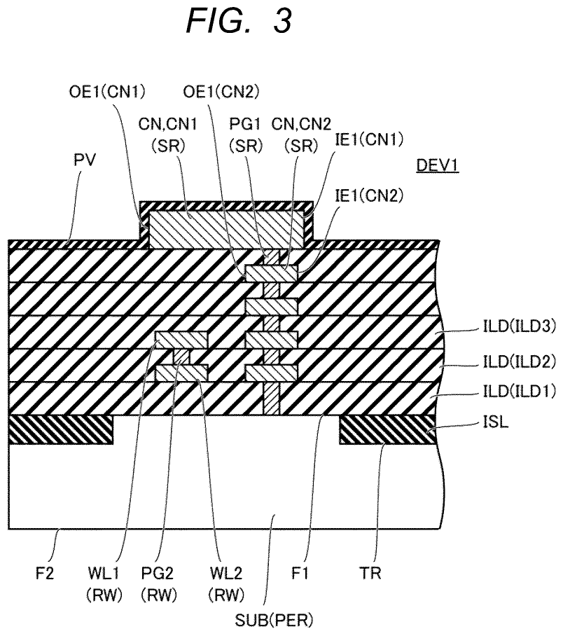

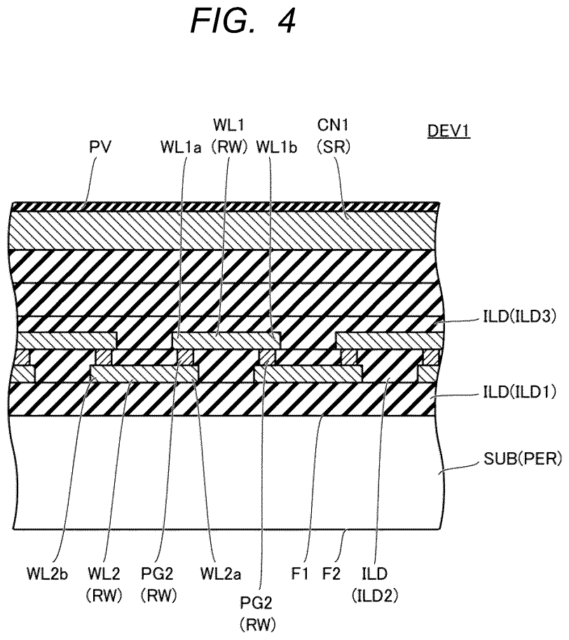

As shown in FIGS. 1 to 4, the semiconductor device DEV1 includes a semiconductor substrate SUB. The semiconductor substrate SUB has a peripheral region PER in plan view. The semiconductor substrate SUB has an upper surface F1 and a lower surface F2 located opposite the upper surface F1. The semiconductor substrate SUB is formed of, for example, monocrystalline silicon.

Although not shown, a source region, a drain region, and a well region are formed within the semiconductor substrate SUB. Also, although not shown, the semiconductor device DEV1 includes a gate dielectric film and a gate electrode. The source region and the drain region are formed on the upper surface F1 so as to be spaced apart from each other. The well region is formed in the upper surface F1 so as to surround the source region and the drain region. The gate dielectric film is formed on the upper surface F1 located between the source region and the drain region. The gate electrode is formed on the gate dielectric film.

The semiconductor device DEV1 includes an element isolation film ISL. A trench TR is formed on the upper surface F1 toward the lower surface F2. The element isolation film ISL is formed within the trench TR. The element isolation film ISL is formed of, for example, silicon oxide. Although not shown, the element isolation film ISL surrounds an above transistor in plan view. This electrically isolates the above transistor from other elements located around it.

The semiconductor device DEV1 includes a plurality of interlayer insulating films ILD. The plurality of interlayer insulating films ILD is laminated on the upper surface F1 along the thickness direction of the semiconductor substrate SUB. The plurality of interlayer insulating films ILD is formed of, for example, silicon oxide. The semiconductor device DEV1 includes a sealing ring SR. The sealing ring SR is formed on the peripheral region PER over an entire circumference of the peripheral region PER. The sealing ring SR includes a plurality of conductors CN and a plurality of plugs PG1.

The plurality of conductors CN is laminated along the thickness direction of the semiconductor substrate SUB. Each of the plurality of conductors CN extends along the peripheral region PER in plan view. The plurality of conductors CN include a conductor CN1 located at the uppermost layer and a plurality of conductors CN2 located below the conductor CN1. The conductor CN1 is formed on one of the plurality of interlayer insulating films ILD located at the uppermost layer. One of the plurality of conductors CN2 is formed on one of the plurality of interlayer insulating films ILD and is covered by another one of the plurality of interlayer insulating films ILD. Each of the plurality of conductors CN has an outer edge OE1 and an inner edge IE1 in plan view. The outer edge OE1 of the conductor CN1 is located outside any of the outer edges OE1 of each of the plurality of conductors CN2 in plan view. A thickness of the conductor CN1 is larger than any of thicknesses of each of the plurality of conductors CN2, for example. The plurality of conductors CN are formed of, for example, aluminum or an aluminum alloy.

Each of the plurality of plugs PG1 is formed within the interlayer insulating film ILD and connects between the conductor CN1 and one of the plurality of conductors CN2 adjacent to the conductor CN1, between two adjacent ones of the plurality of conductors CN2, or between the peripheral region PER and one of the plurality of conductors CN2 adjacent to the peripheral region PER. Each of the plurality of plugs PG1 extends along the peripheral region PER in plan view. The plurality of plugs PG1 are formed of, for example, tungsten.

The semiconductor device DEV1 further includes a routing wiring RW. The routing wiring RW is located between the outer edge OE1 of the conductor CN1 and the outer edges OE1 of each of the plurality of conductors CN2 in plan view. That is, the routing wiring RW overlaps the conductor CN1 in plan view. The routing wiring RW has an outer edge OE2 and an inner edge IE2 in plan view. If the inner edge IE2 is located between the outer edge OE1 of the conductor CN1 and the outer edges OE1 of each of the plurality of conductors CN2 in plan view, the outer edge OE2 may be located outside the outer edge OE1 of the conductor CN1 in plan view. From another point of view, the routing wiring RW may overlap at least partially with the conductor CN1 in plan view.

The routing wiring RW includes a plurality of wirings WL1, a plurality of wirings WL2, a plurality of plugs PG2, and a plurality of plugs PG3. The routing wiring RW is located below the conductor CN1. The routing wiring RW is formed on the peripheral region PER over the entire circumference of the peripheral region PER in plan view, for example.

The plurality of wirings WL1 is formed in a first layer located below the conductor CN1. Also, the plurality of wirings WL2 is formed in a second layer located below the first layer. More specifically, the plurality of wirings WL2 is formed on one of the plurality of interlayer insulating films ILD (interlayer insulating film ILD1) and is covered by one of the plurality of interlayer insulating films ILD formed on an interlayer insulating film ILD1 (interlayer insulating film ILD2). The plurality of wirings WL2 is formed on an interlayer insulating film ILD2 and is covered by one of the plurality of interlayer insulating films ILD formed on the interlayer insulating film ILD2 (interlayer insulating film ILD3). From another point of view, the plurality of wirings WL1 is formed in the same layer as one of the plurality of conductors CN2, and the plurality of wirings WL2 is formed in the same layer as another one of the plurality of conductors CN2.

The plurality of wirings WL1 is arranged spaced apart along the peripheral region PER between two adjacent ones of the plurality of wirings WL1 in plan view. Each of the plurality of wirings WL1 extends along the peripheral region PER in plan view. Each of the plurality of wirings WL1 has an end WL1a and an end WL1b. The plurality of wirings WL2 is arranged spaced apart along the peripheral region PER between two adjacent ones of the plurality of wirings WL2 in plan view. Each of the plurality of wirings WL2 extends along the peripheral region PER in plan view. Each of the plurality of wirings WL2 has an end WL2a and an end WL2b.

One end WL1a of two adjacent ones of the plurality of wirings WL1 and the other end WL1b of two adjacent ones of the plurality of wirings WL1 overlap one end WL2a and one end WL2b of one wiring WL2, respectively, in plan view. Each of the plurality of plugs PG2 connects between the overlapping the end WL1a and the end WL2a in plan view. Each of the plurality of plugs PG3 connects between the overlapping the end WL1b and the end WL2b in plan view. The plurality of wirings WL1 and the plurality of wirings WL2 are formed of, for example, aluminum or an aluminum alloy. The plurality of plugs PG2 and the plurality of plugs PG3 are formed of, for example, tungsten.

The semiconductor device DEV1 further includes a passivation film PV. The passivation film PV is formed on the uppermost interlayer insulating film ILD so as to cover the conductor CN1. The passivation film PV is formed of, for example, silicon nitride.

### MODIFIED EXAMPLE

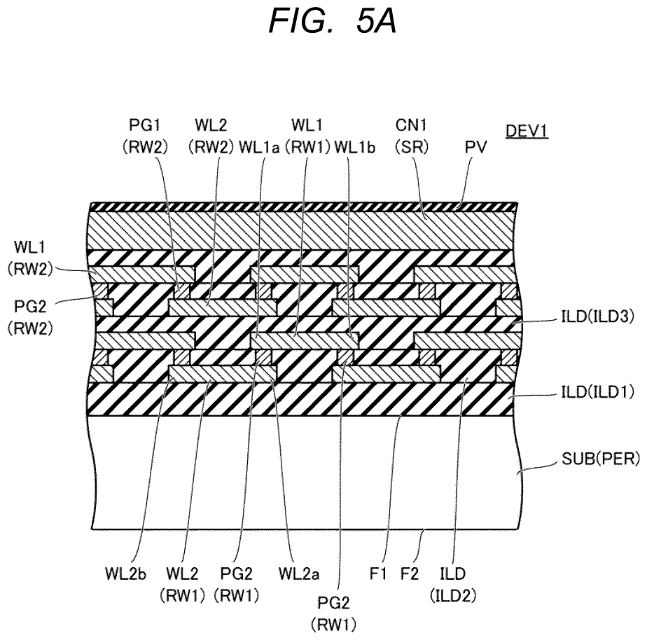

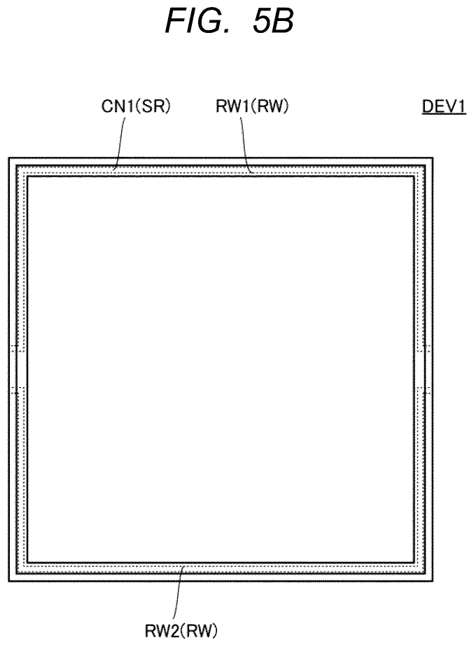

As shown in FIGS. 5A and 5B, the semiconductor device DEV1 may include a plurality of routing wirings RW. In the example shown in FIGS. 5A and 5B, the semiconductor device DEV1 includes two routing wirings RW (routing wiring RW1 and routing wiring RW2). As shown in FIG. 5A, the routing wiring RW1 and the routing wiring RW2 are formed so as to overlap each other in plan view, for example. As shown in FIG. 5B, each of the routing wiring RW1 and the routing wiring RW2 may be formed on the peripheral region PER over at least ¼ of the entire circumference of the peripheral region PER in plan view. Although not shown, the routing wiring RW may be formed on the peripheral region PER over at least ½ of the entire circumference of the peripheral region PER in plan view.

### (Manufacturing Method of Semiconductor Device DEV1)

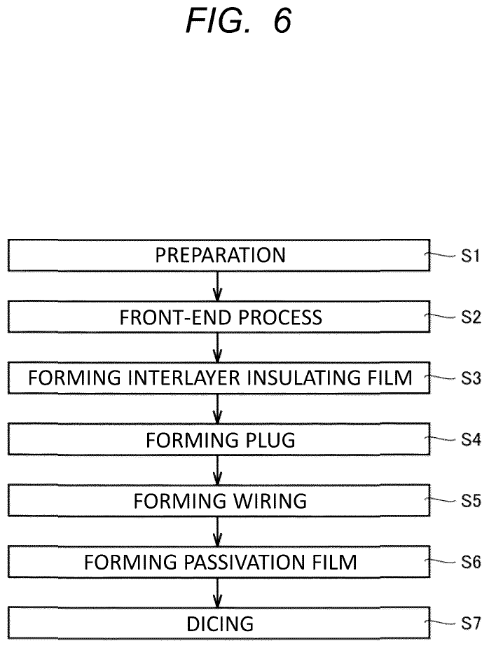

As shown in FIG. 6, the semiconductor device DEV1 includes a preparation step S1, a front-end process step S2, an interlayer insulating film forming step S3, a plug forming step S4, a wiring forming step S5, a passivation film forming step S6, and a dicing step S7.

In the preparation step S1, the semiconductor substrate SUB is prepared. In the front-end process step S2, the source region, the drain region, the well region, the gate dielectric film, and the gate electrode of the transistor are formed. Additionally, in the front-end process step S2, the trench TR is formed on the upper surface F1, and the element isolation film ISL is formed within the trench TR.

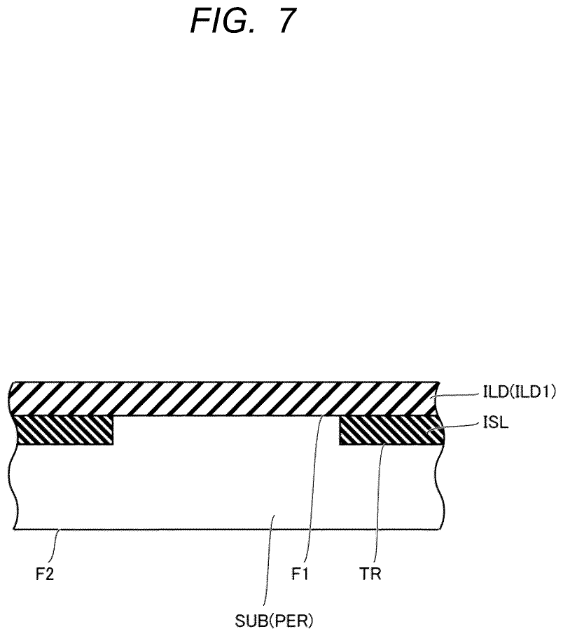

As shown in FIG. 7, in the interlayer insulating film forming step S3, the lowest layer of the interlayer insulating film ILD (interlayer insulating film ILD1) is formed on the upper surface F1 to cover the above-mentioned transistor. In the interlayer insulating film forming step S3, first, a constituent material of the interlayer insulating film ILD is formed on the upper surface F1 by, for example, a CVD (Chemical Vapor Deposition) method. Second, the constituent material of the interlayer insulating film ILD is planarized by, for example, a CMP (Chemical Mechanical Polishing) method. In this way, the interlayer insulating film ILD is formed.

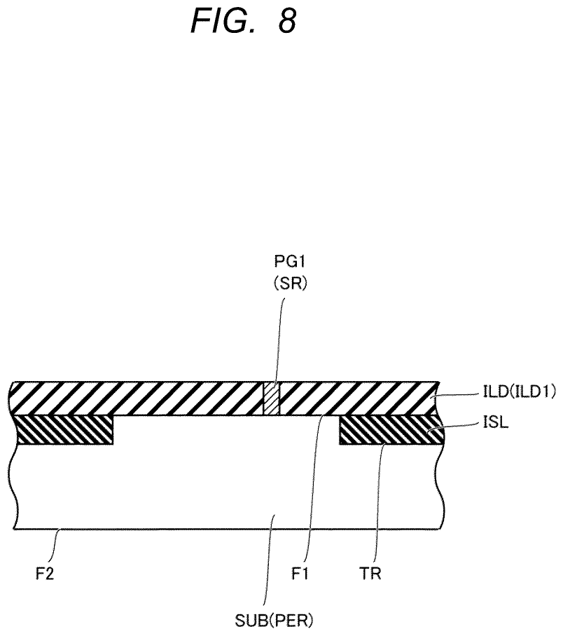

As shown in FIG. 8, in the plug forming step S4, the plug PG1 is formed within the interlayer insulating film ILD1. In the plug forming step S4, first, a resist pattern is formed on the interlayer insulating film ILD1. A resist pattern is formed by applying a photoresist on the interlayer insulating film ILD1 and then exposing and developing the photoresist. Second, a dry etching is performed on the interlayer insulating film ILD using a resist pattern as a mask, forming a through hole within the interlayer insulating film ILD1. Third, a constituent material of the plug PG1 is embedded in the through hole and formed on the interlayer insulating film ILD by, for example, a CVD method. Fourth, the constituent material of the plug PG1 formed outside the through hole is removed by, for example, a CMP method. In this way, the plug PG1 is formed.

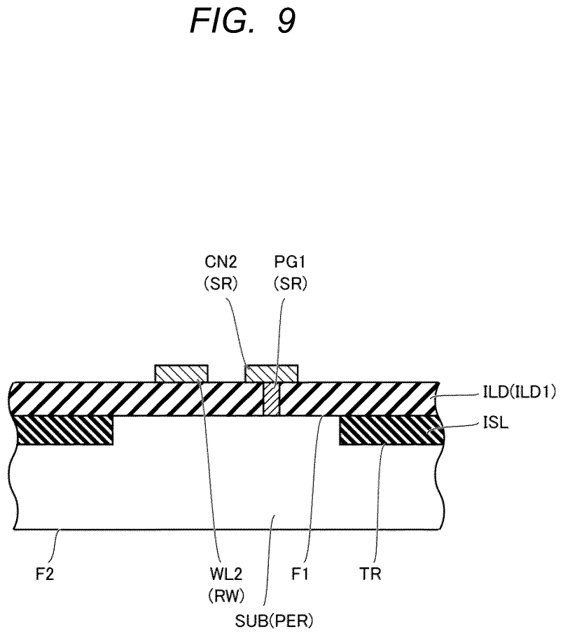

As shown in FIG. 9, in the wiring forming step S5, multiple wirings WL2 are formed on the interlayer insulating film ILD1. In the wiring forming step S5, first, a constituent material of the wiring WL2 is formed on the interlayer insulating film ILD by, for example, sputtering. Second, a resist pattern is formed on the constituent material of the wiring WL2. The resist pattern is formed by applying a photoresist on the constituent material of the wiring WL2 and then exposing and developing the photoresist. Third, the constituent material of the wiring WL2 is patterned by dry etching using a resist pattern as a mask, forming multiple wirings WL2. A patterning of the constituent material of the wiring WL2 also forms the lowest layer conductor CN (conductor CN2).

By repeatedly performing the interlayer insulating film forming step S3, the plug forming step S4, and the wiring forming step S5, the interlayer insulating film ILD2 is formed, and within the interlayer insulating film ILD2, the plug PG1, the plurality of plugs PG2, and the plurality of plugs PG3 are formed. Multiple wirings WL1 are formed on the interlayer insulating film ILD2, and an interlayer insulating film ILD3 is formed on the interlayer insulating film ILD2, with the plurality of interlayer insulating films ILD formed on the interlayer insulating film ILD3. Furthermore, by repeatedly performing the interlayer insulating film forming step S3, the plug forming step S4, and the wiring forming step S5, the plurality of conductors CN2 and the conductor CN1 located outside the lowest layer are also formed.

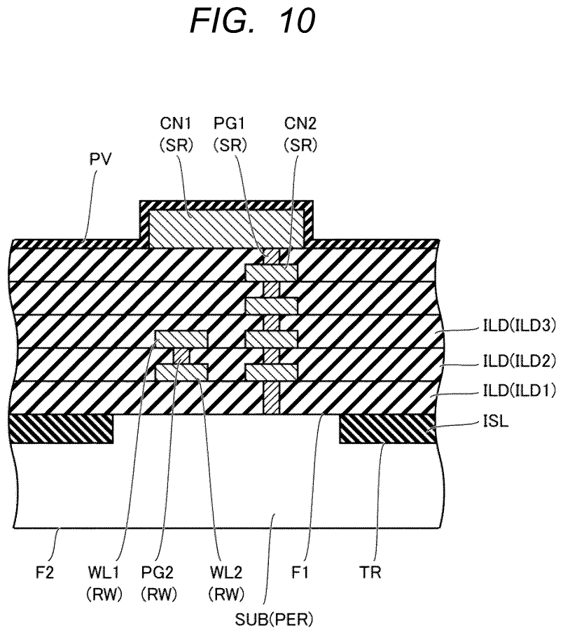

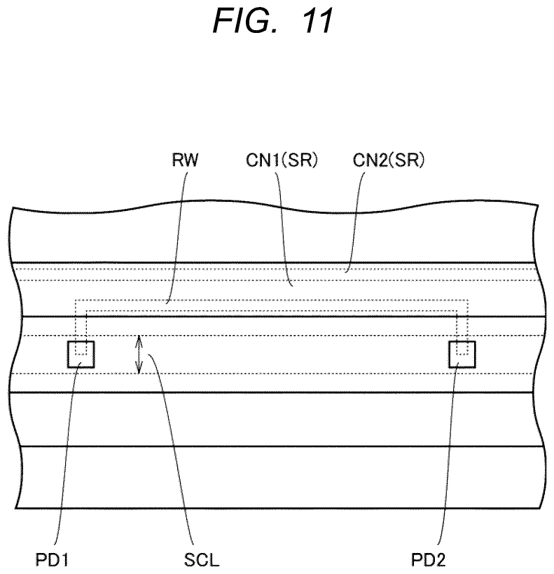

As shown in FIG. 10, in the passivation film forming step S6, the passivation film PV is formed on the uppermost interlayer insulating film ILD to cover the conductor CN1 by, for example, a CVD method. In the dicing step S7, the semiconductor substrate SUB and the plurality of interlayer insulating films ILD are cut along a scribe line SCL (see FIG. 11). This forms a structure of the semiconductor device DEV1 shown in FIGS. 1 to 4.

As shown in FIG. 11, before the dicing step S7 is performed, a pad PD1 and a pad PD2 are formed on the uppermost interlayer insulating film ILD located at the scribe line SCL. The routing wiring RW is electrically connected to the pad PD1 at one end and to the pad PD2 at the other end. By applying voltage between the pad PD1 and the pad PD2 and measuring the electrical resistance value of the routing wiring RW, it is possible to evaluate the quality of the wiring and the plugs formed inside the peripheral region PER in plan view.

### (Effects of Semiconductor Device DEV1)

When the routing wiring RW is formed to overlap with the scribe line SCL in plan view, a width of the scribe line SCL becomes wider, reducing a number of semiconductor devices DEV1 that can be obtained from a single wafer. Particularly, when attempting to pass a large current through the semiconductor device DEV1, it is necessary to increase a thickness of the wiring formed on the uppermost interlayer insulating film ILD (i.e., the wiring formed in the same layer as the conductor CN1), which consequently increases a width of the wiring and the conductor CN1. Therefore, there is a vacant area below the conductor CN1.

In the semiconductor device DEV1, the routing wiring RW is formed on the peripheral region PER to overlap with the conductor CN1 in plan view. Therefore, in the semiconductor device DEV1, the above-mentioned vacant area can be effectively utilized, allowing the width of the scribe line SCL to be reduced, thereby increasing the number of semiconductor devices DEV1 that can be obtained from the single wafer.

### Second Embodiment

A semiconductor device DEV2 according to the second embodiment will be described. Here, the differences from the semiconductor device DEV1 will be mainly explained, and redundant descriptions will not be repeated.

### (Configuration of Semiconductor Device DEV2)

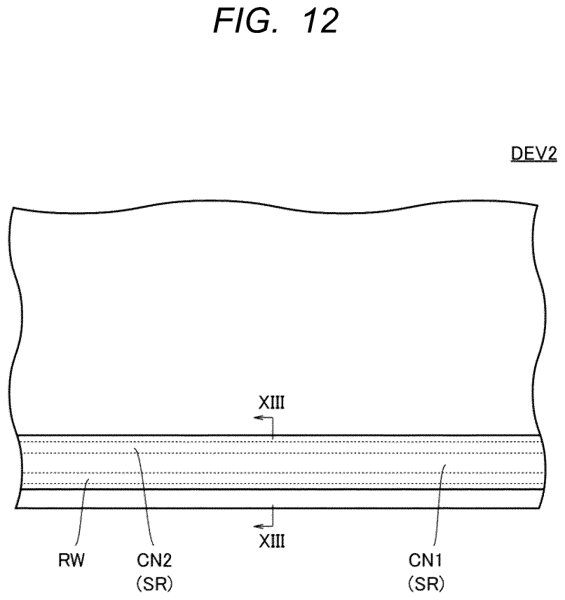

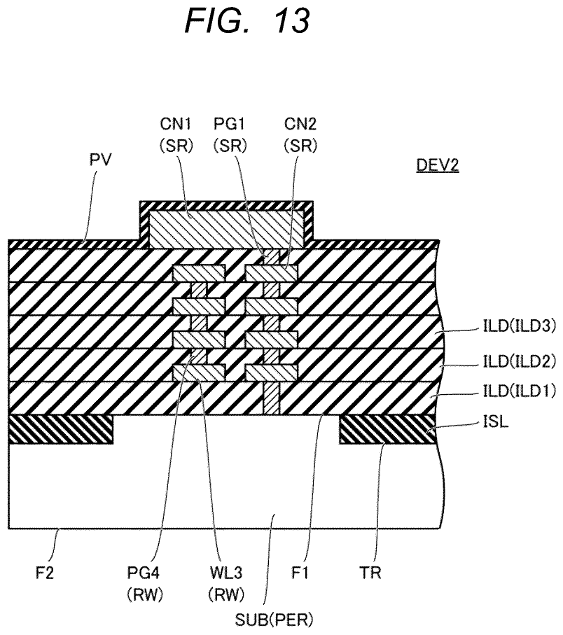

As shown in FIGS. 12 and 13, in the semiconductor device DEV2, the routing wiring RW includes a plurality of wirings WL3 and a plurality of plugs PG4. The plurality of wirings WL3 is positioned below the conductor CN1 and are laminated along the thickness direction of the semiconductor substrate SUB. That is, each of the plurality of wirings WL3 is formed on one of the plurality of interlayer insulating films ILD and is covered by another one of the plurality of interlayer insulating films. Each of the plurality of wirings WL3 extends along the peripheral region PER in plan view.

Each of the plurality of plugs PG4 connects two adjacent ones of the plurality of wirings WL3. From another perspective, the plurality of wirings WL3 is not electrically connected to the conductor CN1 and are not electrically connected to the peripheral region PER (semiconductor substrate SUB). Each of the plurality of plugs PG4 extends along the peripheral region PER in plan view.

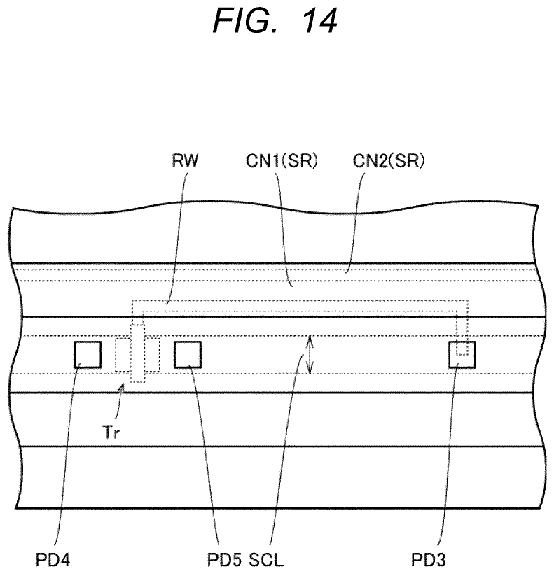

As shown in FIG. 14, in the semiconductor device DEV2, at the stage before the dicing process S7 is performed, pads PD3, PD4, and PD5 are formed on the uppermost interlayer insulating film ILD located on the scribe SCL. Also, in the semiconductor device DEV2, a transistor Tr is formed at a position overlapping the scribe line SCL in plan view.

The routing wiring RW is electrically connected to the pad PD3 at one end and to the gate electrode of the transistor Tr at the other end. The pads PD4 and PD5 are electrically connected to the source region and the drain region of the transistor Tr, respectively. By applying a voltage between the pads PD4 and PD5 and applying a voltage to the pad PD3, the characteristics of the transistor Tr can be measured. Based on the characteristics of the transistor Tr, the characteristics of the transistors formed inside the peripheral region PER in plan view, and thus the performance of the transistors, can be evaluated.

### MODIFIED EXAMPLE

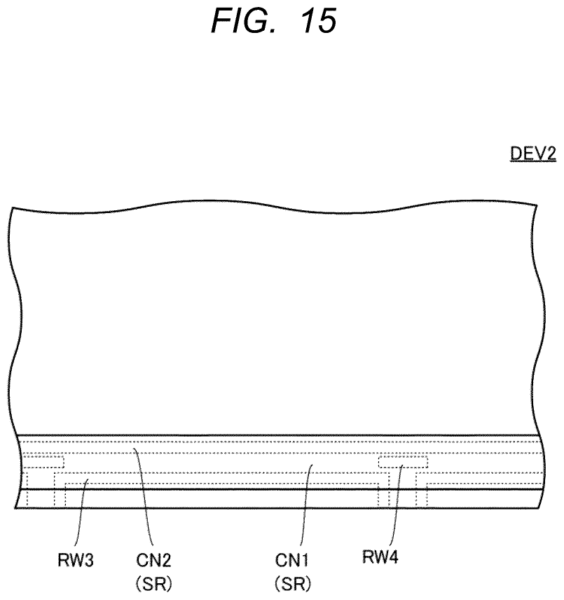

As shown in FIG. 15, the semiconductor device DEV2 may have a plurality of routing wirings RW. In the example shown in FIG. 15, the semiconductor device DEV2 includes a plurality of routing wirings RW3 and a plurality of routing wirings RW4 as the routing wiring RW. Each of the plurality of routing wirings RW3 is arranged spaced apart between two adjacent ones of the plurality of routing wirings RW3 along the peripheral region PER in plan view. Each of the plurality of routing wirings RW4 is positioned inside each of the plurality of routing wirings RW3 in plan view. Also, each of the plurality of routing wirings RW4 is arranged to face the gap between two adjacent ones of the plurality of routing wirings RW3.

### (Effects of Semiconductor Device DEV2)

In the semiconductor device DEV2, since the routing wiring RW is formed to overlap the conductor CN1 in plan view, the width of the scribe line SCL can be reduced, to the similar semiconductor device DEV1, and the number of semiconductor devices DEV1 obtained from the single wafer can be increased. In the semiconductor device DEV2, since the routing wiring RW has a structure similar to the sealing ring SR, the routing wiring RW not only serves as an electrical connection but also acts as a sealing ring to suppress a propagation of cracks generated during dicing. As a result, according to the semiconductor device DEV2, the propagation of cracks generated during dicing can be further suppressed.

If the semiconductor device DEV2 has the plurality of routing wirings RW3 and the plurality of routing wirings RW4, the crack that attempts to propagate from the gap between the plurality of routing wirings RW3 can be stopped by the routing wiring RW4, further suppressing the propagation of cracks generated during dicing.

### Third Embodiment

A semiconductor device DEV3 according to the third embodiment will be described. Here, differences from the described, and semiconductor device DEV2 will be mainly redundant description will not be repeated.

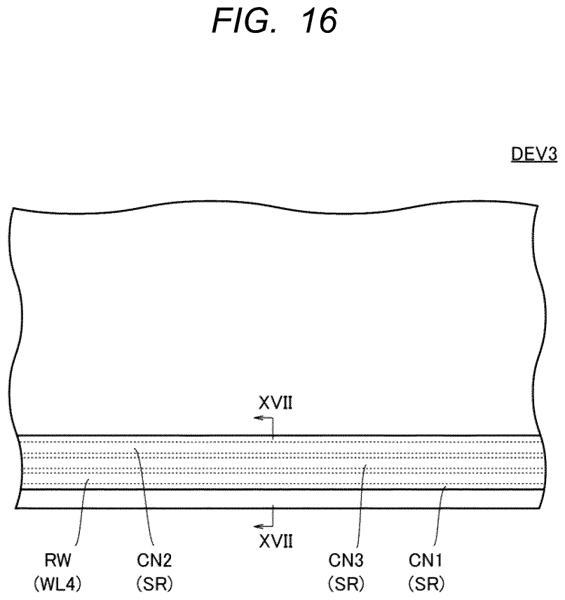

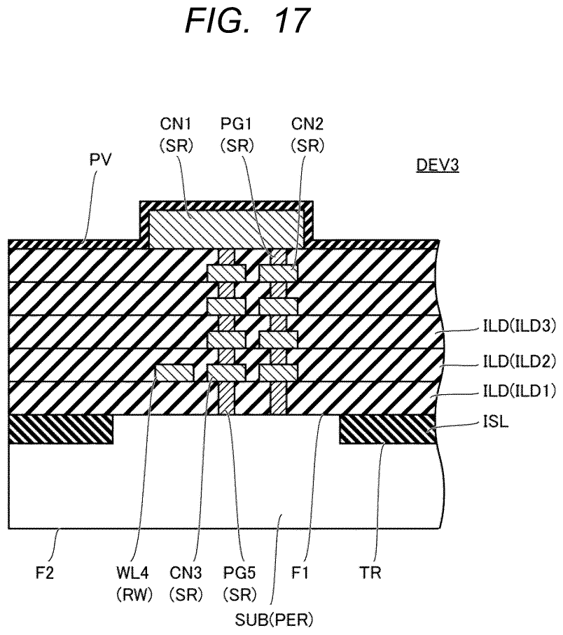

As shown in FIGS. 16 and 17, in the semiconductor device DEV3, the routing wiring RW includes the wiring WL4. The wiring WL4 is formed on one of the plurality of interlayer insulating films ILD and is covered by another one of the plurality of interlayer insulating films ILD. The wiring WL4 extends along the peripheral region PER in plan view.

In the semiconductor device DEV3, the sealing ring SR may further include a plurality of plugs PG5. Also, in the semiconductor device DEV3, a plurality of conductors CN may further include a plurality of conductors CN3. The plurality of conductors CN3 is located in a lower layer than the conductor CN1. The plurality of conductors CN3 is located between the inner edge IE1 of the conductor CN1 and the inner edge IE1 of each of the plurality of conductors CN2 in plan view. Each of the plurality of plugs PG5 connects between one of the plurality of conductors CN3 adjacent to the conductor CN1, between two adjacent conductors CN3, and between one of the plurality of conductors CN3 adjacent to the peripheral region PER and the peripheral region PER.

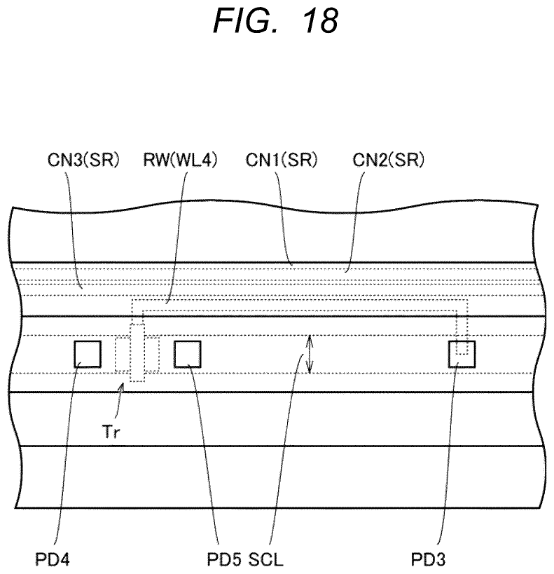

As shown in FIG. 18, in the semiconductor device DEV3, at the stage before the dicing process S7 is performed, the pads PD3, PD4, and PD5 are formed on the uppermost interlayer insulating film ILD located on the scribe line SCL. In the semiconductor device DEV3, a transistor Tr is formed at a position overlapping the scribe line SCL in plan view. The routing wiring RW is electrically connected to the pad PD3 at one end and to the gate electrode of the transistor Tr at the other end. The pads PD4 and PD5 are electrically connected to the source region and the drain region of the transistor Tr, respectively.

### MODIFIED EXAMPLE

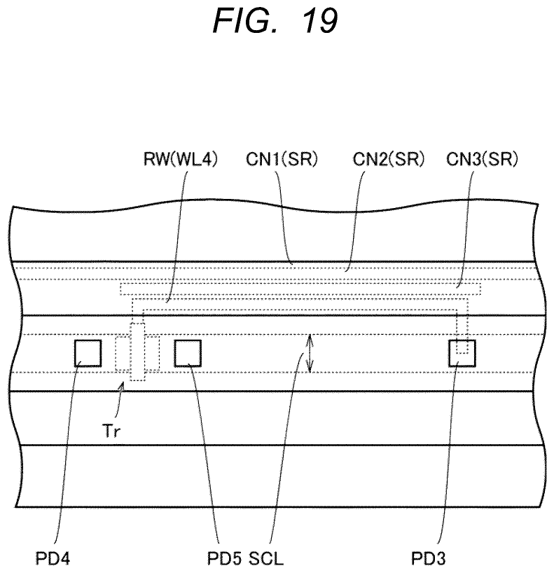

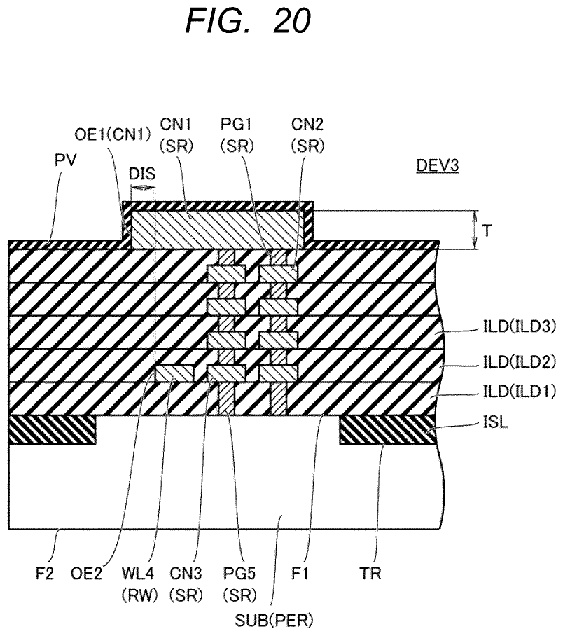

As shown in FIG. 19, in the semiconductor device DEV3, the plurality of conductors CN3 may not be formed over the entire circumference of the peripheral region PER in plan view. For example, the plurality of conductors CN3 may be formed only at positions facing the routing wiring RW (wiring WL4) in plan view. As shown in FIG. 20, A thickness of the conductor CN1 is defined as a thickness T. A distance between the outer edge OE2 (outer edge of wiring WL4) and the outer edge OE1 in plan view is defined as a distance DIS. The distance DIS may be, for example, 0.5 times or more the thickness T. The outer edge OE2 may be located outside or inside the outer edge OE1 in plan view.

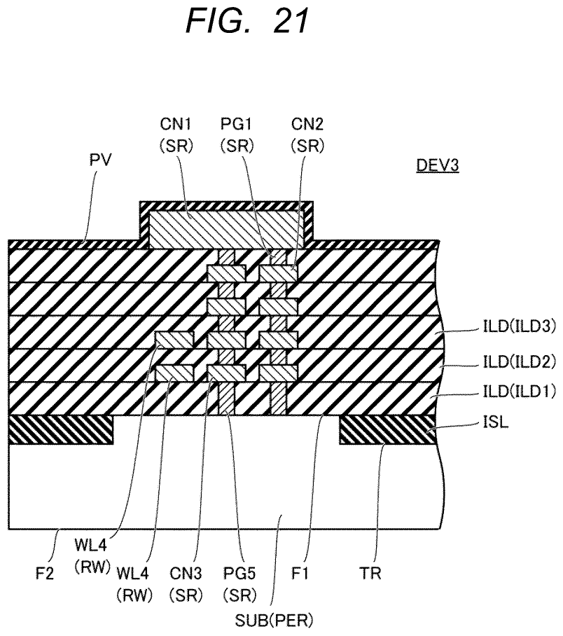

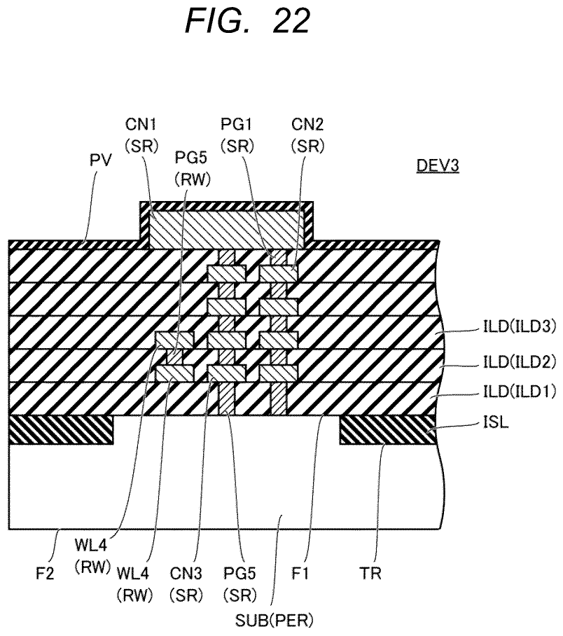

As shown in FIG. 21, in the semiconductor device DEV3, the routing wiring RW may include a plurality of wirings WL4. The plurality of wirings WL4 is stacked along the thickness direction of the semiconductor substrate SUB. As shown in FIG. 22, the routing wiring RW may include a plurality of plugs PG6. Each of the plurality of plugs PG5 connects between two adjacent wirings WL4.

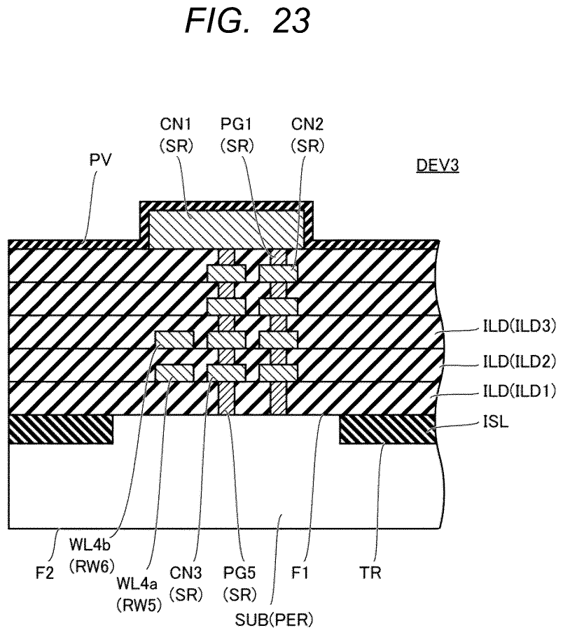

As shown in FIG. 23, the semiconductor device DEV3 may include a plurality of routing wirings RW. In the example shown in FIG. 23, the semiconductor device DEV3 includes two routing wirings RW (routing wiring RW5 and routing wiring RW6). The routing wiring RW5 includes a wiring WL4a, and the routing wiring RW6 includes a wiring WL4b. The wiring WL4a and the wiring WL4b are formed in different layers. In the example shown in FIG. 23, the wiring WL4a is formed on the interlayer insulating film ILD1, and the wiring WL4b is formed on the interlayer insulating film ILD2.

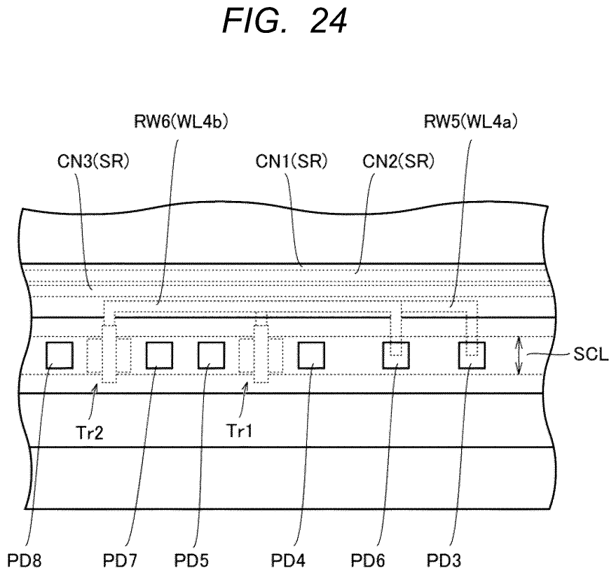

As shown in FIG. 24, in the semiconductor device DEV3, at the stage before the dicing process S7 is performed, pads PD6, PD7, and PD8 are formed on the uppermost interlayer insulating film ILD located on the scribe line SCL, in addition to the pads PD3, PD4, and PD5. In the semiconductor device DEV3, the transistors Tr1 and Tr2 are formed at positions overlapping the scribe line SCL in plan view. The routing wiring RW5 is electrically connected to the pad PD3 at one end and to the gate electrode of the transistor Tr1 at the other end. The pads PD4 and PD5 are electrically connected to the source region and the drain region of the transistor Tr1, respectively. The routing wiring RW6 is electrically connected to the pad PD6 at one end and to the gate electrode of the transistor Tr2 at the other end. The pads PD7 and PD8 are electrically connected to the source region and the drain region of the transistor Tr2, respectively.

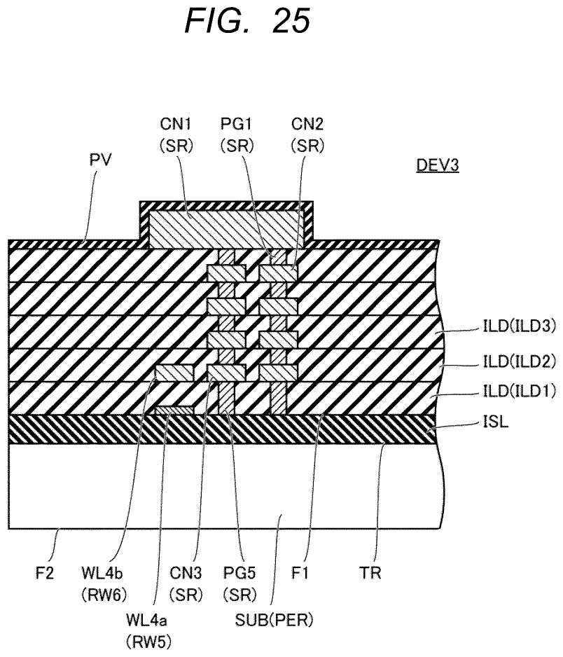

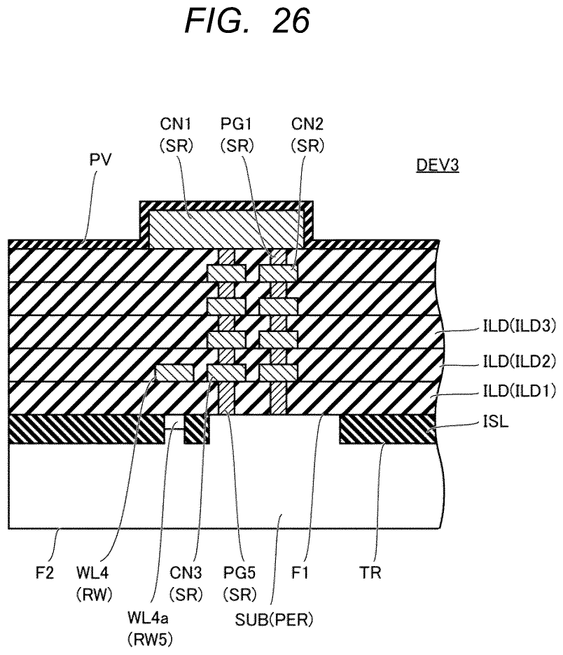

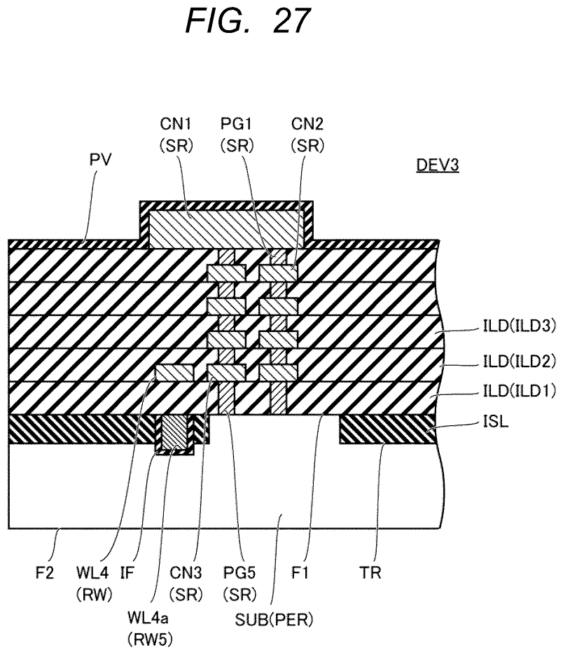

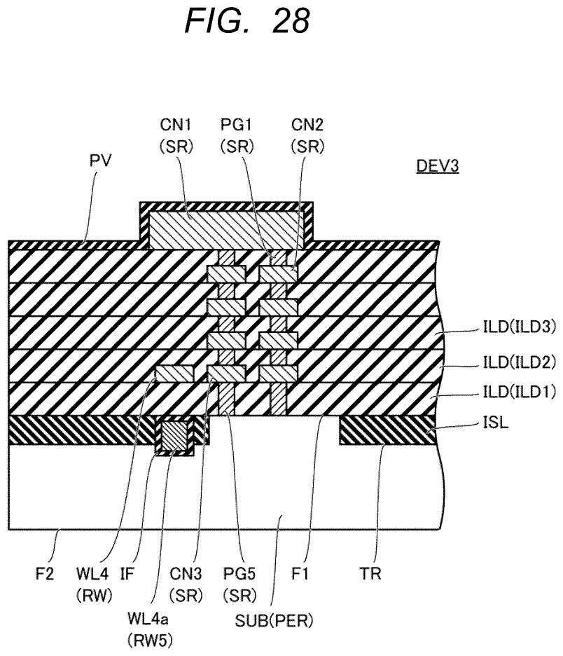

As shown in FIG. 25, the wiring WL4a may be formed on the element isolation film ISL. In this case, the wiring WL4a is formed of, for example, polycrystalline silicon containing dopants. As shown in FIGS. 26 to 28, the wiring WL4a may be formed within the semiconductor substrate SUB. In the example shown in FIG. 26, the wiring WL4a is an impurity diffusion layer formed on the upper surface F1. In the example shown in FIG. 27, the wiring WL4a is formed of polycrystalline silicon containing dopants. In this case, the semiconductor substrate SUB and the element isolation film ISL have a first trench formed therein, and an insulating film IF is embedded in the first trench. A second trench is formed within the insulating film IF, and the wiring WL4a is embedded in the second trench. As shown in FIG. 28, the wiring WL4a may be embedded in the second trench by the insulating film IF. That is, the wiring WL4a and the wiring WL4b may be formed in different layers below the conductor CN1.

### (Effects of Semiconductor Device DEV3)

In the semiconductor device DEV3, the sealing ring SR further includes the plurality of conductors CN2 and the plurality of plugs PG5. That is, in the semiconductor device DEV3, the sealing ring SR has a double structure. Therefore, according to the semiconductor device DEV3, the propagation of cracks generated during dicing can be further suppressed.

When attempting to pass a large current through the semiconductor device DEV3, it is necessary to increase the thickness of the wiring formed on the uppermost interlayer insulating film ILD (i.e., the wiring formed in the same layer as the conductor CN1), which results in an increase in the thickness T. When the thickness T increases, stress tends to act at positions overlapping the outer edge OE1 in plan view. If the distance DIS is 0.5 times or more the thickness T, the routing wiring RW is arranged to avoid positions overlapping the outer edge OE1 in plan view, thereby reducing the stress acting on the routing wiring RW.

When the routing wiring RW includes the plurality of wirings WL4, the cross-sectional area of the routing wiring RW increases, allowing the electrical resistance value of the routing wiring RW to be reduced. Additionally, when the semiconductor device DEV3 includes a plurality of routing wirings RW, and each of the plurality of routing wirings RW includes the wiring WL4 formed in different layers, the installation flexibility of the routing wiring RW is enhanced.

Although the invention made by the present inventors has been described in detail based on the embodiments, it is needless to say that the present invention is not limited to the above-described embodiments and can be variously modified without departing from the gist thereof.

What is claimed is:

1. A semiconductor device comprising:
a semiconductor substrate having a peripheral region;
a sealing ring formed on the peripheral region of the semiconductor substrate so as to extend along the peripheral region; and
at least one routing wiring formed so as to extend along the peripheral region, wherein
the sealing ring is configured by laminating a first conductor located at an uppermost layer, a plurality of second conductors located below the first conductor, and a plurality of first plugs connecting with the first conductor, the plurality of second conductors and the semiconductor substrate respectively,
an outer edge of the first conductor is located outside any of outer edges of each of the plurality of second conductors, in plan view,
the at least one routing wiring is located between the outer edge of the first conductor and the outer edges of each of the plurality of second conductors, in plan view,
the at least one routing wiring is formed on or in the peripheral region of the semiconductor substrate so as to be located below the first conductor.

2. The semiconductor device according to claim 1, wherein
the at least one routing wiring includes a plurality of first wirings, a plurality of second wirings, a plurality of second plugs,
the plurality of first wirings is arranged apart from each other in a direction along the peripheral region, in plan view,
the plurality of second wirings is located below the plurality of first wirings and is arranged apart from each other in the direction along the peripheral region, in plan view, and
the each of the plurality of first wirings and the each of the plurality of second wirings are connected by the plurality of second plugs.

3. The semiconductor device according to claim 1, wherein
the at least one routing wiring is formed over an entire circumference of the peripheral region, in plan view.

4. The semiconductor device according to claim 1, wherein
the at least one routing wiring is formed more than a half of an entire circumference of the peripheral region.

5. The semiconductor device according to claim 1, wherein
the at least one routing wiring is formed more than a quarter of an entire circumference of the peripheral region.

6. The semiconductor device according to claim 1, wherein
the at least one routing wiring includes a first routing wiring and a second routing wiring formed by overlapping the first routing wiring, in plan view.

7. The semiconductor device according to claim 1, wherein
the at least one routing wiring includes a plurality of third wirings and a plurality of third plugs, and
the each of the plurality of third wirings are stacked and are connected by the plurality of third plugs.

8. The semiconductor device according to claim 1, wherein
the at least one routing wiring includes a third routing wiring and a fourth routing wiring located inside the third routing wiring, in plan view.

9. The semiconductor device according to claim 1, wherein
the at least one routing wiring includes a plurality of third routing wirings and a plurality of fourth routing wirings,
the plurality of third routing wirings is arranged apart from each other in a direction along the peripheral region, in plan view,
each of the plurality of fourth routing wirings faces a space between two adjacent of the plurality of third routing wirings and is located inside the plurality of third routing wirings, in plan view.

10. The semiconductor device according to claim 1, wherein
the sealing ring is further configured:
a plurality of third conductors located below the first conductor; and
a plurality of fourth plugs connecting with the first conductor, the plurality of third conductors and the semiconductor substrate respectively, and
the plurality of third conductors located between an inner edge of the first conductor and an inner edges of each of the plurality of second conductors, in plan view.

11. The semiconductor device according to claim 1, wherein
a distance between an outer edge of the at least one routing wiring and the outer edge of the first conductor is 0.5 times or more a thickness of the first conductor.
